(19) United States
(12) Patent Application Publication
(10) Pub. No.: US 2025/0075304 A1
(43) Pub. Date: Mar. 6, 2025

(54) SILICON-BASED MASK, MANUFACTURING METHOD, AND DISPLAY PANEL

(71) Applicant: BOE TECHNOLOGY GROUP CO., LTD., Beijing (CN)

(72) Inventors: Jinxiang Xue, Beijing (CN); Weijie Wang, Beijing (CN); Zhongyuan Sun, Beijing (CN); Fengjie Zhang, Beijing (CN); Lu Wang, Beijing (CN)

(73) Assignee: BOE TECHNOLOGY GROUP CO., LTD., Beijing (CN)

(21) Appl. No.: 18/562,556

(22) PCT Filed: Feb. 21, 2023
(86) PCT No.: PCT/CN2023/077306

§ 371 Date: Nov. 20, 2023

(51) Int. Cl. C23C 14/04; H10K 59/12; H10K 71/16

(52) U.S. Cl. CPC C23C 14/042; H10K 59/1201; H10K 71/166

(57) ABSTRACT

The present disclosure provides a silicon-based mask, a manufacturing method, and a display panel. The silicon-based mask includes a first silicon wafer and a second silicon wafer laminated one on another. The first silicon wafer includes a first via hole, the second silicon wafer includes a second via hole, an orthogonal projection of a wall of the first via hole onto the second silicon wafer surrounds the second via hole, and under a same etching condition, an etching rate of the second silicon wafer is smaller than an etching rate of the first silicon wafer.

### TECHNICAL FIELD

The present disclosure relates to the field of display technology, in particular to a silicon-based mask, a manufacturing method thereof, and a display panel.

### BACKGROUND

With the development of the display technology, the performance of display products is highly demanded. In order to improve the display quality of the display products, the high-resolution display products have attracted more and more attentions. During the manufacture of the high-resolution display product, a mask for achieving an ultra-high resolution needs to be used.

### SUMMARY

An object of the present disclosure is to provide a silicon-based mask, a manufacturing method thereof and a display panel, so as to solve the problem in the related art.

In order to achieve the above-mentioned object, the present disclosure provides the following technical solutions.

In one aspect, the present disclosure provides in some embodiments a silicon-based mask, including a first silicon wafer and a second silicon wafer laminated one on another. The first silicon wafer includes a first via hole, the second silicon wafer includes a second via hole, an orthogonal projection of a wall of the first via hole onto the second silicon wafer surrounds the second via hole, and under a same etching condition, an etching rate of the second silicon wafer is smaller than an etching rate of the first silicon wafer.

In a possible embodiment of the present disclosure, under the same etching condition, a ratio of the etching rate of the first silicon wafer to the etching rate of the second silicon wafer is greater than or equal to 80.

In a possible embodiment of the present disclosure, a pore size d of the second via hole satisfies 2 μm≤d≤20 μm.

In a possible embodiment of the present disclosure, a slope angle of the first via hole is smaller than a slope angle of the second via hole.

In a possible embodiment of the present disclosure, a thickness of the first silicon wafer is greater than a thickness of the second silicon wafer.

In a possible embodiment of the present disclosure, a crystal orientation [110] of the first silicon wafer is coaxial with a crystal orientation [111] of the second silicon wafer, or the crystal orientation [110] of the first silicon wafer is perpendicular to the crystal plane [111] of the second silicon wafer.

In a possible embodiment of the present disclosure, a doping type of the first silicon wafer includes a P-type or an N-type, and a doping type of the second silicon wafer includes a P-type or an N-type.

In a possible embodiment of the present disclosure, the silicon-based mask further includes a first protection layer and a second protection layer, the first protection layer is located on a side of the first silicon wafer away from the second silicon wafer, and the second protection layer is located on a side of the second silicon wafer away from the first silicon wafer.

In a possible embodiment of the present disclosure, each of the first protection layer and the second protection layer includes a magnetic material layer.

In another aspect, the present disclosure provides in some embodiments a display panel, including an organic light-emitting material layer manufactured using the above-mentioned silicon-based mask.

In yet another aspect, the present disclosure provides in some embodiments a method for manufacturing a silicon-based mask, including: providing a first silicon wafer; forming a second silicon wafer on the first silicon wafer, under a same etching condition, an etching rate of the second silicon wafer being smaller than an etching rate of the first silicon wafer; and forming a first via hole in the first silicon wafer through wet etching, and forming a second via hole in the second silicon wafer through dry etching, an orthogonal projection of a wall of the first via hole onto the second silicon wafer surrounding the second via hole.

In a possible embodiment of the present disclosure, the forming the first via hole in the first silicon wafer through wet etching and forming the second via hole in the second silicon wafer through dry etching specifically includes: forming a first protection layer on a side of the first silicon wafer away from the second silicon wafer, and forming a second protection layer on a side of the second silicon wafer away from the first silicon wafer; patterning the first protection layer; forming the first via hole in the first silicon wafer through wet etching with the patterned first protection layer as a mask; and forming the second via hole in the second protection layer and the second silicon wafer through dry etching.

In a possible embodiment of the present disclosure, the forming the first via hole in the first silicon wafer through wet etching and forming the second via hole in the second silicon wafer through dry etching specifically includes: forming the second via hole in the second silicon wafer through dry etching; forming a first protection layer on a side of the first silicon wafer away from the second silicon wafer, and forming a second protection layer on a side of the second silicon wafer away from the first silicon wafer, the second protection layer covering a wall of the second via hole; patterning the first protection layer; and forming the first via hole in the first silicon wafer through wet etching with the patterned first protection layer as a mask.

In a possible embodiment of the present disclosure, the forming the second via hole in the second silicon wafer through dry etching specifically includes: forming a photoresist layer on a side of the second silicon wafer away from the first silicon wafer; patterning the photoresist layer; forming the second via hole in the second silicon wafer through dry etching with the patterned photoresist layer as a mask; and removing the patterned photoresist layer.

In a possible embodiment of the present disclosure, the forming the first via hole in the first silicon wafer through wet etching specifically includes etching the first silicon wafer to form the first via hole through a potassium hydroxide etching solution or a tetramethylammonium hydroxide etching solution.

In a possible embodiment of the present disclosure, the method further includes, subsequent to forming the first via hole and the second via hole, removing the first protection layer and the second protection layer.

In a possible embodiment of the present disclosure, the forming the first protection layer and the second protection layer specifically includes forming the first protection layer and the second protection layer using an inorganic material, and the removing the first protection layer and the second protection layer specifically includes removing the first protection layer and the second protection layer through wet etching using an etching solution.

In a possible embodiment of the present disclosure, the forming the second silicon wafer on the first silicon wafer specifically includes epitaxially growing the second silicon wafer on the first silicon wafer.

### BRIEF DESCRIPTION OF THE DRAWINGS

The following drawings are provided to facilitate the understanding of the present disclosure, and constitute a portion of the description. These drawings and the following embodiments are for illustrative purposes only, but shall not be construed as limiting the present disclosure. In these drawings,

FIG. 1 is a schematic view showing a silicon-based mask according to one embodiment of the present disclosure;

FIG. 2 is another schematic view showing the silicon-based mask according to one embodiment of the present disclosure;

FIG. 3 is a schematic view showing the manufacture of the silicon-based mask according to one embodiment of the present disclosure; and

FIG. 4 is another schematic view showing the manufacture of the silicon-based mask according to one embodiment of the present disclosure.

### DETAILED DESCRIPTION

The present disclosure will be described hereinafter in conjunction with the drawings and embodiments.

In the related art, in a display product, usually a light-emitting layer of a pixel is formed through a Fine Metal Mask (FMM), and the FMM is mad of an invar material, so it is difficult to manufacture the display product with an ultra-high resolution.

It is found through researches that, the display product with an ultra-high resolution may be manufactured through a silicon-based mask, e.g., a Silicon-On-Insulator (SOI) mask. However, the SOI mask is expensive, so the manufacture cost of the display product may increase.

For the existing silicon-based masks of the other types, an etching rate needs to be reduced during the manufacture, so as to improve the etching uniformity and prevent the occurrence of an over-etching phenomenon. At this time, the tact time increases remarkably, so it is adverse to the mass production thereof. Hence, there is an urgent need to provide a silicon-based mask with low manufacture cost and high efficiency.

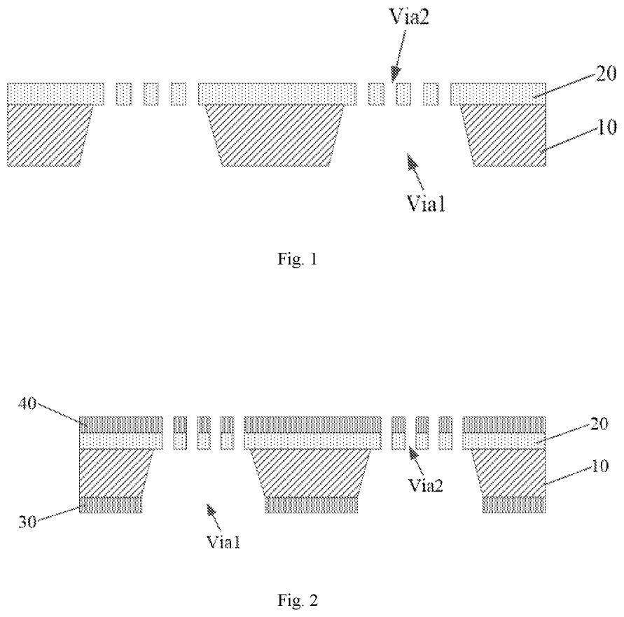

As shown in FIG. 1, the present disclosure provides in some embodiments a silicon-based mask, which includes a first silicon wafer 10 and a second silicon wafer 20 laminated one on another. The first silicon wafer 10 includes a first via hole Via1, the second silicon wafer 20 includes a second via hole Via2, an orthogonal projection of a wall of the first via hole Via1 onto the second silicon wafer 20 surrounds the second via hole Via2, and under a same etching condition, an etching rate of the second silicon wafer 20 is smaller than an etching rate of the first silicon wafer 10.

Illustratively, the first silicon wafer 10 and the second silicon wafer 20 are each made of silicon crystals, and each of the first silicon wafer 10 and the second silicon wafer 20 includes a plurality of crystal orientations of the silicon crystals.

It should be appreciated that, different crystal orientations in a silicon-based film layer have different etching rates under a same wet etching condition. For example, for a crystal orientation [110], a crystal orientation [111] and a crystal orientation [100], under the same etching condition, there exists such a relationship as v[110]>v[100]>v[111], where v[110] represents an etching rate of silicon in the crystal orientation [110], v[100] represents an etching rate of silicon in the crystal orientation [100], and v[111] represents an etching rate of silicon in the crystal orientation [111]. The etching rate in the crystal orientation [111] is the smallest, so the crystal orientation [111] is the most stable crystal orientation. Illustratively, when a KOH solution is used as an etching solution, a ratio of v[110] to v[111] is around 100.

Illustratively, a thickness of the first silicon wafer 10 is, but not limited to, within a range of 400 μm to 600 μm, with endpoints being inclusive. The first silicon wafer 10 serves as a substrate for the silicon-based mask, so as to support the silicon-based mask.

Illustratively, a plurality of first via holes Via1 is formed in the first silicon wafer 10 through wet etching, and the plurality of first via holes Via1 is arranged in an array form. A plurality of second via holes Via2 is formed in the second silicon wafer 20 through dry etching, and the plurality of second via holes Via2 is arranged in an array form. The plurality of second via holes Via2 is divided into a plurality of groups corresponding to the plurality of first via holes Via1 respectively, and the orthogonal projection of the wall of the first via hole Via1 onto the second silicon wafer 20 surrounds the corresponding group of second via holes Via2.

Illustratively, a pore size of the first via hole Via1 is larger than a pore size of the second via hole Via2.

During the manufacture of the silicon-based mask in the embodiments of the present disclosure, the first silicon wafer 10 with a larger etching rate is provided, and then the second silicon wafer 20 is formed on the first silicon wafer 10. Under the same etching condition, the etching rate of the second silicon wafer 20 is smaller than the etching rate of the first silicon wafer 10, so during the formation of the first via hole Via1 in the first silicon wafer 10 through wet etching, an etching solution with a high etching rate is used, so as to etch the first silicon wafer 10 at a high etching rate. In addition, the second silicon wafer 20 has excellent stability and a low etching rate, so during the etching of the first silicon wafer 10 through the etching solution having a high etching rate and after etching the first silicon wafer 10, it is able to prevent the second silicon wafer 20 from being influenced remarkably.

According to the silicon-based mask in the embodiments of the present disclosure, the second silicon wafer 20 functions as an automatic stop layer. As a result, it is able to etch the first silicon wafer 10 at a high etching rate, prevent the first silicon wafer 10 from being over-etched during the wet etching, and prevent the second silicon wafer 20 from being influenced remarkably, thereby to improve the manufacture efficiency and yield of the silicon-based wafer.

In addition, both the first silicon wafer 10 and the second silicon wafer 20 are made of a monocrystalline silicon material, so as to reduce the manufacture cost of the silicon-based mask.

In some embodiments of the present disclosure, the ratio of the etching rate of the first silicon wafer 10 to the etching rate of the second silicon wafer 20 is greater than or equal to 80 under the same etch condition.

Illustratively, the ratio of the etching rate of the first silicon wafer 10 to the etching rate of the second silicon wafer 20 is about 100 when the KOH etching solution is used.

In some embodiments of the present disclosure, the pore size d of the second via hole Via2 satisfies 2 μm≤d≤20 μm.

Illustratively, the pore size of the second via hole Via2 is, but not limited to, 2 μm, 3.8 μm, 4 μm, 6 μm, 8 μm, 10 μm, 12 μm, 14 μm, 16 μm, 18 μm, or 20 μm.

In the above-mentioned silicon-based mask, when the pore size d of the second via hole Via2 satisfies 2 μm≤d≤20 μm, it is able to provide the silicon-based mask with micro through-holes having a small pore size.

In some embodiments of the present disclosure, a slope angle of the first via hole Via1 is smaller than a slope angle of the second via hole Via2.

Illustratively, the first via hole Via1 is etched using a KOH solution or a TMAH solution in a crystal orientation [110] having a slope angle of 54.7°.

Illustratively, the first via hole Via1 has a slope angle within, but not limited to, a range of 50° to 60°, with endpoints being inclusive. Illustratively, the slope angle of the first via hole Via1 is 50°, 52°, 54°, 56°, 58° or 60°.

Illustratively, the second via hole Via2 is formed through dry etching, and the slope angle of the second via hole Via2 is greater than 0° and smaller than or equal to 5°.

Illustratively, during the evaporation through the silicon-based mask, a pore size of the second via hole Via2 at an end close to a display panel is smaller than a pore size of the second via hole Via2 at an end away from the display panel.

When the slope angle of the first via hole Via1 is smaller than the slope angle of the second via hole Via2, it is able for an evaporation material to pass through the second via hole Via2 conveniently.

In some embodiments of the present disclosure, the thickness of the first silicon wafer 10 is greater than the thickness of the second silicon wafer 20.

Illustratively, the thickness of the first silicon wafer 10 is within a range of 480 μm to 520 μm, with endpoints being inclusive. Illustratively, the first silicon wafer 10 has a thickness of 485 μm, 490 μm, 495 μm, 500 μm, 505 μm, 510 μm or 515 μm.

Illustratively, the thickness of the second silicon wafer 20 is smaller than or equal to 20 μm. For example, the second silicon wafer 20 has a thickness of 2 μm, 5 m, 8 μm, 10 μm, 12 μm, 15 μm or 18 μm.

When the thickness of the first silicon wafer 10 is greater than the thickness of the second silicon wafer 20, it is able for the first silicon wafer 10 to support the second silicon wafer 20 in a better manner.

In some embodiments of the present disclosure, the crystal orientation [110] of the first silicon wafer is coaxial with the crystal orientation [111] of the second silicon wafer, or the crystal orientation [110] of the first silicon wafer is perpendicular to the crystal plane [111] of the second silicon wafer.

Based on the above, a crystal plane [110] of the second silicon wafer is located on a side away from the first silicon wafer 10. After the first silicon wafer 10 is etched through the etching solution, the etching solution is not in contact with the crystal plane [110] of the second silicon wafer. A crystal plane [111] of the second silicon wafer is etched at a small etching rate, so the second silicon wafer 20 functions as an automatic stop layer.

Based on the above, the etching rate of the second silicon wafer 20 is smaller than the etching rate of the first silicon wafer 10 under the same etching condition. When the first via hole Via1 is formed in the first silicon wafer 10 through wet etching, an etching solution with a high etching rate is used, so as to etch the first silicon wafer 10 at a high etching rate. In addition, the second silicon wafer 20 has excellent stability and a low etching rate, so during the etching of the first silicon wafer 10 at a high etching rate and after etching the first silicon wafer 10, it is able to prevent the second silicon wafer 20 from being influenced remarkably. The second silicon wafer 20 functions as an automatic stop layer. As a result, it is able to etch the first silicon wafer 10 at a high etching rate, prevent the first silicon wafer 10 from being over-etched during the wet etching, and prevent the second silicon wafer 20 from being influenced remarkably, thereby to improve the manufacture efficiency and yield of the silicon-based mask.

In some embodiments of the present disclosure, a doping type of the first silicon wafer includes a P-type or an N-type, and a doping type of the second silicon wafer includes a P-type or an N-type.

Illustratively, a phosphorus element is doped so as to obtain N-type Si and a boron element is doped so as to obtain P-type Si.

Through doping the first silicon wafer and the second silicon wafer, it is able to improve the performance of the silicon-based mask, e.g., adjust a stress of the silicon-based mask.

As shown in FIG. 2, in some embodiments of the present disclosure, the silicon-based mask further includes a first protection layer 30 on a side of the first silicon wafer 10 away from the second silicon wafer 20 and a second protection layer 40 on a side of the second silicon wafer 20 away from the first silicon wafer 10.

It should be appreciated that, the first protection layer 30 and the second protection layer 40 reserved in the silicon-based mask are patterned protection layers, i.e., a first via hole Via1 corresponding to the first via hole Via1 in the first silicon wafer 10 is formed in the first protection layer 30, and a second via hole Via2 corresponding to the second via hole Via2 in the second silicon wafer 20 is formed in the second protection layer 40.

When the first protection layer 30 and the second protection layer 40 are reserved, it is able to improve the stress and flatness of the silicon-based mask.

Illustratively, a thickness of each of the first protection layer 30 and the second protection layer 40 depends on an etching thickness of each of the first silicon wafer 10 and the second silicon wafer 20 and the ratio of the etching rate of the first silicon wafer 10 to the etching rate of the second silicon wafer 20. Each of the first protection layer 30 and the second protection layer 40 includes a first film layer and a second film layer laminated one on another, the first film layer is made of SiOx and located between the second film layer and the silicon wafer, the second film layer is made of SiNx, a thickness of the first film layer is 1000 Å, and a thickness of the second film layer is 1500 Å, but the present disclosure is not limited thereto. When the first film layer is made of SiOx, it is able to increase an adhesion force between the protection layer and the silicon wafer.

In some embodiments of the present disclosure, each of the first protection layer 30 and the second protection layer 40 includes a magnetic material layer.

Illustratively, the magnetic material is Ni, Fe, or the like, and a magnitude of a magnetic force is adjusted through adjusting an area and a thickness of the magnetic material layer.

When the first protection layer 30 and the second protection layer 40 both include the magnetic material layer, during the evaporation, it is able for the silicon-based mask to be attached to an evaporation device in a better manner.

The present disclosure further provides in some embodiments a display panel including an organic light-emitting material layer which is formed through the above-mentioned silicon-based mask.

Illustratively, the display panel includes, but not limited to, an organic light-emitting diode display panel or a stretchable, flexible display panel.

Illustratively, the display panel includes a plurality of sub-pixels each including a sub-pixel driving circuitry and a light-emitting element. The sub-pixel driving circuitry is coupled to an anode of the light-emitting element, and configured to apply a driving signal to the light-emitting element so as to drive the light-emitting element to emit light. Illustratively, the light-emitting element includes an organic light-emitting material layer formed through the above-mentioned silicon-based mask.

Illustratively, during the manufacture of the display panel, a mother board including a plurality of display panels is fabricated and aligned with the silicon-based mask, so that the plurality of display panels corresponds to a plurality of first via holes Via1 in the silicon-based mask respectively. A group of second via holes Via2 corresponding to each first via hole Via1 are used to form the organic light-emitting material layer in the corresponding display panel.

According to the display panel in the embodiments of the present disclosure, the organic light-emitting material layer is formed through the above-mentioned silicon-based mask, so it is able to form the small-size organic light-emitting material layers at a high density, thereby to provide the display panel with a high resolution.

In addition, due to the high manufacture efficiency and yield as well as the low manufacture cost of the silicon-based mask, it is able to reduce the manufacture cost of the display panel.

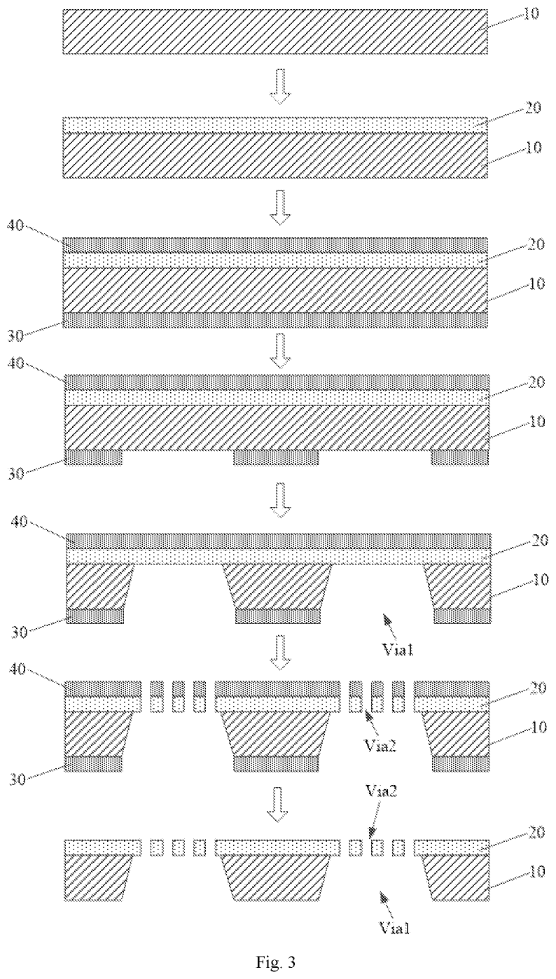

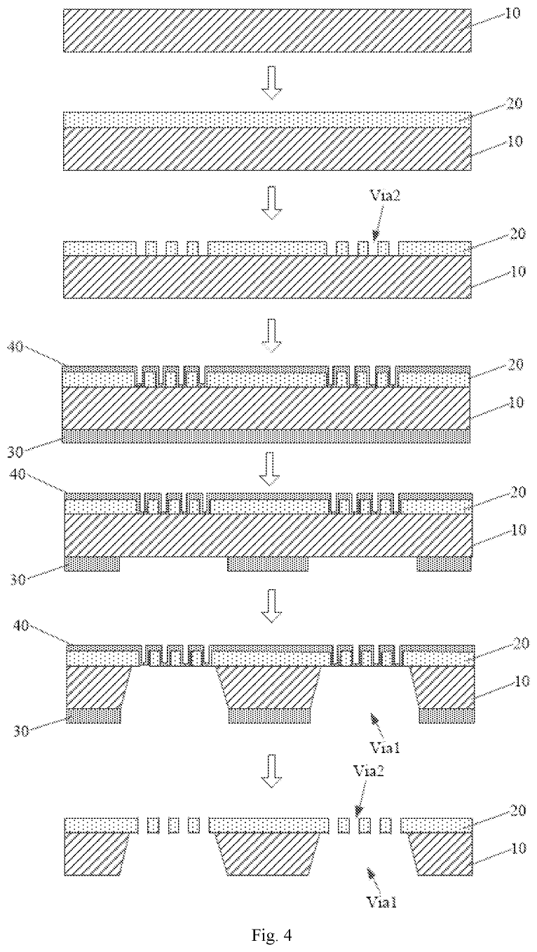

With reference to FIGS. 3 and 4, the present disclosure further provides in some embodiments a method for manufacturing the above-mentioned silicon-based mask, which includes: providing the first silicon wafer 10; forming the second silicon wafer 20 on the first silicon wafer 10, under same etching conditions, an etching rate of the second silicon wafer 20 being smaller than an etching rate of the first silicon wafer 10; and forming the first via hole Via1 in the first silicon wafer 10 through wet etching, and forming the second via hole Via2 in the second silicon wafer 20 through dry etching; an orthogonal projection of a wall of the first via hole Via1 onto the second silicon wafer 20 surrounding the second via hole Via2.

According to the method in the embodiments of the present disclosure, the first silicon wafer 10 with a larger etching rate is provided, and then the second silicon wafer 20 is formed on the first silicon wafer 10. Under the same etching condition, the etching rate of the second silicon wafer 20 is smaller than the etching rate of the first silicon wafer 10, so during the formation of the first via hole Via1 in the first silicon wafer 10 through wet etching, an etching solution with a high etching rate is used, so as to etch the first silicon wafer 10 at a high etching rate. In addition, the second silicon wafer 20 has excellent stability and a low etching rate, so during the etching of the first silicon wafer 10 through the etching solution having a high etching rate and after etching the first silicon wafer 10, it is able to prevent the second silicon wafer 20 from being influenced remarkably

Hence, when the silicon-based mask is manufactured through the method in the embodiment of the present disclosure, the second silicon wafer 20 functions as an automatic stop layer. As a result, it is able to etch the first silicon wafer 10 at a high etching rate, prevent the first silicon wafer 10 from being over-etched during the wet etching, and prevent the second silicon wafer 20 from being influenced remarkably, thereby to improve the manufacture efficiency and yield of the silicon-based wafer.

In addition, both the first silicon wafer 10 and the second silicon wafer 20 are made of a monocrystalline silicon material, so as to reduce the manufacture cost of the silicon-based mask.

As shown in FIG. 3, in some embodiments of the present disclosure, the forming the first via hole Via1 in the first silicon wafer 10 through wet etching and forming the second via hole Via2 in the second silicon wafer 20 through dry etching specifically includes: forming a first protection layer 30 on the side of the first silicon wafer 10 away from the second silicon wafer 20 and forming a second protection layer 40 on the side of the second silicon wafer 20 away from the first silicon wafer 10; patterning the first protection layer 30; forming the first via hole Via1 in the first silicon wafer 10 through wet etching with the patterned first protection layer 30 as a mask; and forming the second via hole Via2 in the second protection layer 40 and the second silicon wafer 20 through dry etching.

Illustratively, the first protection layer 30 is deposited on a surface of the first silicon wafer 10 away from the second silicon wafer 20, and the second protection layer 40 is deposited on a surface of the second silicon wafer 20 away from the first silicon wafer 10.

Illustratively, the patterning the first protection layer 30 specifically includes: forming a photoresist layer on a side of the first protection layer 30 away from the second protection layer 40; exposing and developing the photoresist layer through a mask, so as to form a photoresist reserved region and a photoresist unreserved region, the photoresist unreserved region corresponding to a region where the first via hole Via1 is located, and the photoresist reserved region corresponding to regions other than the region where the first via hole Via1 is located; and removing the first protection layer 30 in the photoresist unreserved region through wet etching with the remaining photoresist layer as a mask, and reserving the first protection layer 30 in the photoresist reserved region, so as to pattern the first protection layer 30. The remaining photoresist layer is then removed, so as to expose the patterned first protection layer 30.

Illustratively, the forming a first via hole Via1 in the first silicon wafer 10 through wet etching with the patterned first protection layer 30 as a mask specifically includes placing a silicon-based structure with the patterned first protection layer 30 into a corresponding etching solution, and etching a part of the first silicon wafer not covered by the first protection layer 30 until the first via hole Via1 is formed and the second silicon wafer 20 is exposed.

Illustratively, the forming the second via hole Via2 in the second protection layer 40 and the second silicon wafer 20 through dry etching specifically includes: forming a photoresist layer on a side of the second protection layer 40 away from the first protection layer 30; exposing and developing the photoresist layer so as to form a photoresist reserved region and a photoresist unreserved region, the photoresist unreserved region corresponding to a region where the second via hole Via2 is located, and the photoresist reserved region corresponding to regions other than the region where the second via hole Via2 is located; and forming the second via hole Via2 in the second protection layer 40 and the second silicon wafer 20 through dry etching with the remaining photoresist layer as a mask, and removing the remaining photoresist layer so as to expose the patterned second protection layer 40.

In the above-mentioned method, the first silicon wafer 10 having a high etching rate serves as a substrate, and the second silicon wafer 20 having a low etching rate and serving as an automatic stop layer is formed on the first silicon wafer 10. In addition, the first protection layer 30 is formed on a side of the first silicon wafer 10 away from the second silicon wafer 20, and the second protection layer 40 is formed on a side of the second silicon wafer 20 away from the first silicon wafer 10. During the formation of the first via hole Via1 in the first silicon wafer 10 through wet etching, a part of the first silicon wafer 10 in the regions other than the region where the first via hole Via1 is located is protected from being etched by the etching solution through the first protection layer 30, and the second silicon wafer 20 is protected from being etched by the etching solution through the second protection layer 40. Moreover, during the formation of the second via hole Via2 in the second silicon wafer 20 through dry etching, a part of the second silicon wafer 20 in the regions other than the region where the second via hole Via2 is located is protected from being etched through the second protection layer 40, and the first silicon wafer 10 is protected from being etched through the first protection layer 30.

According to the method in the embodiments of the present disclosure, it is able to etch the first silicon wafer 10 at a high etching rate, prevent the first silicon wafer 10 from being over-etched through the wet etching, and prevent the second silicon wafer 20 from being influenced remarkably, thereby to improve the manufacture efficiency and yield of the silicon-based mask. In addition, through the first protection layer 30 and the second protection layer 40, it is able to further improve the yield of the silicon-based mask.

As shown in FIG. 4, in some embodiments of the present disclosure, the forming the first via hole Via1 in the first silicon wafer 10 through wet etching and forming the second via hole Via2 in the second silicon wafer 20 through dry etching specifically includes: forming the second via hole Via2 in the second silicon wafer 20 through dry etching; forming the first protection layer 30 on a side of the first silicon wafer 10 away from the second silicon wafer 20, and forming the second protection layer 40 on the side of the second silicon wafer 20 away from the first silicon wafer 10, the second protection layer 40 covering a wall of the second via hole Via2; patterning the first protection layer 30; and forming the first via hole Via1 in the first silicon wafer 10 through wet etching with the patterned first protection layer 30 as a mask.

Illustratively, subsequent to forming the second silicon wafer 20 on the first silicon wafer 10 and prior to forming the first protection layer 30 and the second protection layer 40, the second via hole Via2 is formed in the second silicon wafer 20 through dry etching.

Illustratively, the first protection layer 30 is deposited on a surface of the first silicon wafer 10 away from the second silicon wafer 20, the second protection layer 40 is deposited on a surface of the second silicon wafer 20 away from the first silicon wafer 10, the second protection layer 40 at least partially fills in the second via hole Via2, and the second protection layer 40 covers a wall and a bottom of the second via hole Via2.

Illustratively, the patterning the first protection layer 30 specifically includes: forming a photoresist layer on a side of the first protection layer 30 away from the second protection layer 40; exposing and developing the photoresist layer through a mask, so as to form a photoresist reserved region and a photoresist unreserved region, the photoresist unreserved region corresponding to a region where the first via hole Via1 is located, and the photoresist reserved region corresponding to regions other than the region where the first via hole Via1 is located; and removing the first protection layer 30 in the photoresist unreserved region through wet etching with the remaining photoresist layer as a mask, and reserving the first protection layer 30 in the photoresist reserved region, so as to pattern the first protection layer 30. The remaining photoresist layer is then removed, so as to expose the patterned first protection layer 30. Illustratively, the forming the first via hole Via1 in the first silicon wafer 10 through wet etching with the patterned first protection layer 30 as a mask specifically includes placing a silicon-based structure with the patterned first protection layer 30 into a corresponding etching solution, and etching a part of the first silicon wafer not covered by the first protection layer 30 until the first via hole Via1 is formed and the second silicon wafer 20 is exposed.

In the above-mentioned method, the first silicon wafer 10 having a high etching rate serves as a substrate, and the second silicon wafer 20 having a low etching rate and serving as an automatic stop layer is formed on the first silicon wafer 10. In addition, the first protection layer 30 is formed on a side of the first silicon wafer 10 away from the second silicon wafer 20, and the second protection layer 40 is formed on a side of the second silicon wafer 20 away from the first silicon wafer 10. During the formation of the first via hole Via1 in the first silicon wafer 10 through wet etching, a part of the first silicon wafer 10 in the regions other than the region where the first via hole Via1 is located is protected from being etched by the etching solution through the first protection layer 30, and the second silicon wafer 20 is protected from being etched by the etching solution through the second protection layer 40, so it is able to ensure the accuracy of the second via hole Via2.

According to the method in the embodiments of the present disclosure, it is able to etch the first silicon wafer 10 at a high etching rate, prevent the first silicon wafer 10 from being over-etched through the wet etching, and prevent the second silicon wafer 20 from being influenced remarkably, thereby to improve the manufacture efficiency and yield of the silicon-based mask. In addition, through the first protection layer 30 and the second protection layer 40, it is able to further improve the yield of the silicon-based mask.

In some embodiments of the present disclosure, the forming the second via hole Via2 in the second silicon wafer 20 through dry etching specifically includes: forming a photoresist layer on a side of the second silicon wafer 20 away from the first silicon wafer 10; patterning the photoresist layer; forming the second via hole Via2 in the second silicon wafer 20 through dry etching with the patterned photoresist layer as a mask; and removing the patterned photoresist layer.

Illustratively, the photoresist layer is formed on a side of the second silicon wafer 20 away from the first silicon wafer 10. Next, the photoresist layer is exposed and developed through a corresponding mask, so as to form a photoresist reserved region and a photoresist unreserved region, i.e., pattern the photoresist layer. The photoresist unreserved region corresponds to a region where the second via hole Via2 is located, and the photoresist unreserved region corresponds to regions other than the region where the second via hole Via2 is located. Next, the second via hole Via2 is formed in the second silicon wafer 20 through dry etching with the remaining photoresist layer as a mask, and then the remaining photoresist layer is removed, so as to expose the second silicon wafer 20.

In the above-mentioned method, it is able to form the second via hole Via2 with high precision on the second silicon wafer 20, without any influence on the first silicon wafer 10.

In some embodiments of the present disclosure, the forming the first via hole Via1 in the first silicon wafer 10 through wet etching specifically includes etching the first silicon wafer 10 to form the first via hole Via1 using a potassium hydroxide KOH etching solution or a tetramethylammonium hydroxide (TMAH) etching solution.

It should be appreciated that, the etching solution for forming the first via hole Via1 is limited to potassium hydroxide and tetramethylammonium hydroxide.

As shown in FIGS. 3 and 4, in some embodiments of the present disclosure, the method further includes, subsequent to forming the first via hole Via1 and the second via hole Via2, removing the first protection layer 30 and the second protection layer 40.

In the above-mentioned method, both the first protection layer 30 and the second protection layer 40 are removed, so as to provide a light and thin silicon-based mask.

In some embodiments of the present disclosure, the forming the first protection layer 30 and the second protection layer 40 specifically includes forming the first protection layer 30 and the second protection layer 40 using an inorganic material. The removing the first protection layer 30 and the second protection layer 40 specifically includes removing the first protection layer 30 and the second protection layer 40 through wet etching using an etching solution.

Illustratively, the inorganic material includes, but not limited to, SiOx or SiNx.

Illustratively, a SiOx material is deposited to form the first protection layer 30 and the second protection layer 40, and the first protection layer 30 and the second protection layer 40 are etched off through an HF etching solution.

Illustratively, a SiNx material is deposited to form the first protection layer 30 and the second protection layer 40, and the first protection layer 30 and the second protection layer 40 are etched off through an H3PO4 etching solution.

In some embodiments of the present disclosure, after the formation of the first via hole Via1 and the second via hole Via2, the first protection layer 30 and the second protection layer 40 are reserved.

In the above-mentioned method, when the first protection layer 30 and the second protection layer 40 are reserved after the formation of the first via hole Via1 and the second via hole Via2, it is able to improve the stress and the flatness of the silicon-based mask.

In some embodiments of the present disclosure, the step forming the second silicon wafer 20 on the first silicon wafer 10 specifically includes epitaxially growing the second silicon wafer 20 on the first silicon wafer 10.

Illustratively, the second silicon wafer 20 is epitaxially grown on the first silicon wafer 10 through epitaxial growth equipment, and a thickness of the second silicon wafer 20 determines a depth of the second via hole. The thickness and uniformity of the second silicon wafer 20 depends mainly on the epitaxial growth equipment. As a result, it is able to provide the second silicon wafer 20 with a lower film thickness, and improve the uniformity of second silicon wafer 20, thereby to improve the applicability of the silicon-based mask.

It should be appreciated that, a display device including the above-mentioned display panel includes any product or member having a display function, e.g., television, display, digital photo frame, mobile phone or tablet computer. The display device further includes a flexible circuit board, a printed circuit board and a back plate.

In the embodiments of the present disclosure, the order of the steps is not limited to the serial numbers thereof. For a person skilled in the art, any change in the order of the steps shall also fall within the scope of the present disclosure if without any creative effort.

It should be further appreciated that, the above embodiments have been described in a progressive manner, and the same or similar contents in the embodiments have not been repeated, i.e., each embodiment has merely focused on the difference from the others. Especially, the method embodiments are substantially similar to the product embodiments, and thus have been described in a simple manner.

It should be further appreciated that, the expression “at a same layer” refers to that the film layers are arranged on a same structural layer. Alternatively, for example, the film layers on a same layer may be layer structures formed through forming thin layers for forming specific patterns through a single-film-forming process and then patterning the film layers with a same mask through a single patterning process. Depending on different specific patterns, a single patterning process may include multiple exposing, development or etching processes, and the specific patterns in the layer structure may be continuous or discontinuous. These specific patterns may also be arranged at different levels or have different thicknesses.

Unless otherwise defined, any technical or scientific term used herein shall have the common meaning understood by a person of ordinary skills. Such words as “first” and “second” used in the specification and claims are merely used to differentiate different components rather than to represent any order, number or importance. Similarly, such words as “one” or “one of” are merely used to represent the existence of at least one member, rather than to limit the number thereof. Such words as “include” or “including” intends to indicate that an element or object before the word contains an element or object or equivalents thereof listed after the word, without excluding any other element or object. Such words as “connect/connected to” or “couple/coupled to” may include electrical connection, direct or indirect, rather than to be limited to physical or mechanical connection. Such words as “on”, “under”, “left” and “right” are merely used to represent relative position relationship, and when an absolute position of the object is changed, the relative position relationship will be changed too.

It should be further appreciated that, in the case that such an element as layer, film, region or substrate is arranged “on” or “under” another element, it may be directly arranged “on” or “under” the other element, or an intermediate element may be arranged therebetween.

In the above description, the features, structures, materials or characteristics may be combined in any embodiment or embodiments in an appropriate manner.

The above embodiments are for illustrative purposes only, but the present disclosure is not limited thereto. Obviously, a person skilled in the art may make further modifications and improvements without departing from the spirit of the present disclosure, and these modifications and improvements shall also fall within the scope of the present disclosure.

1. A silicon-based mask, comprising a first silicon wafer and a second silicon wafer laminated one on another, wherein the first silicon wafer comprises a first via hole, the second silicon wafer comprises a second via hole, an orthogonal projection of a wall of the first via hole onto the second silicon wafer surrounds the second via hole, and under a same etching condition, an etching rate of the second silicon wafer is smaller than an etching rate of the first silicon wafer.

2. The silicon-based mask according to claim 1, wherein under the same etching condition, a ratio of the etching rate of the first silicon wafer to the etching rate of the second silicon wafer is greater than or equal to 80.

3. The silicon-based mask according to claim 1, wherein a pore size d of the second via hole satisfies 2 μm≤d≤20 μm.

4. The silicon-based mask according to claim 1, wherein a slope angle of the first via hole is smaller than a slope angle of the second via hole.

5. The silicon-based mask according to claim 1, wherein a thickness of the first silicon wafer is greater than a thickness of the second silicon wafer.

6. The silicon-based mask according to claim 5, wherein a crystal orientation [110] of the first silicon wafer is coaxial with a crystal orientation [111] of the second silicon wafer, or the crystal orientation [110] of the first silicon wafer is perpendicular to the crystal plane [111] of the second silicon wafer.

7. The silicon-based mask according to claim 1, wherein a doping type of the first silicon wafer comprises a P-type or an N-type, and a doping type of the second silicon wafer comprises a P-type or an N-type.

8. The silicon-based mask according to claim 1, further comprising a first protection layer and a second protection layer, wherein the first protection layer is located on a side of the first silicon wafer away from the second silicon wafer, and the second protection layer is located on a side of the second silicon wafer away from the first silicon wafer.

9. The silicon-based mask according to claim 8, wherein each of the first protection layer and the second protection layer comprises a magnetic material layer.

10. A display panel comprising an organic light-emitting material layer manufactured using the silicon-based mask according to claim 1.

11. A method for manufacturing the silicon-based mask according to claim 1, comprising:
providing a first silicon wafer;
forming a second silicon wafer on the first silicon wafer, under a same etching condition, an etching rate of the second silicon wafer being smaller than an etching rate of the first silicon wafer; and
forming a first via hole in the first silicon wafer through wet etching, and forming a second via hole in the second silicon wafer through dry etching, an orthogonal projection of a wall of the first via hole onto the second silicon wafer surrounding the second via hole.

12. The method according to claim 11, wherein the forming the first via hole in the first silicon wafer through wet etching and forming the second via hole in the second silicon wafer through dry etching specifically comprises:
forming a first protection layer on a side of the first silicon wafer away from the second silicon wafer, and forming a second protection layer on a side of the second silicon wafer away from the first silicon wafer;
patterning the first protection layer; forming the first via hole in the first silicon wafer through wet etching with the patterned first protection layer as a mask; and
forming the second via hole in the second protection layer and the second silicon wafer through dry etching.

13. The method according to claim 11, wherein the forming the first via hole in the first silicon wafer through wet etching and forming the second via hole in the second silicon wafer through dry etching specifically comprises:
forming the second via hole in the second silicon wafer through dry etching;
forming a first protection layer on a side of the first silicon wafer away from the second silicon wafer, and forming a second protection layer on a side of the second silicon wafer away from the first silicon wafer, the second protection layer covering a wall of the second via hole; patterning the first protection layer; and
forming the first via hole in the first silicon wafer through wet etching with the patterned first protection layer as a mask.

14. The method according to claim 13, wherein the forming the second via hole in the second silicon wafer through dry etching specifically comprises:
forming a photoresist layer on a side of the second silicon wafer away from the first silicon wafer;
patterning the photoresist layer;
forming the second via hole in the second silicon wafer through dry etching with the patterned photoresist layer as a mask; and
removing the patterned photoresist layer.

15. The method according to claim 12, wherein the forming the first via hole in the first silicon wafer through wet etching specifically comprises etching the first silicon wafer to form the first via hole through a potassium hydroxide etching solution or a tetramethylammonium hydroxide etching solution.

16. The method according to claim 12, further comprising, subsequent to forming the first via hole and the second via hole, removing the first protection layer and the second protection layer.

17. The method according to claim 16, wherein the forming the first protection layer and the second protection layer specifically comprises forming the first protection layer and the second protection layer using an inorganic material, and the removing the first protection layer and the second protection layer specifically comprises removing the first protection layer and the second protection layer through wet etching using an etching solution.

18. The method according to claim 11, wherein the forming the second silicon wafer on the first silicon wafer specifically comprises epitaxially growing the second silicon wafer on the first silicon wafer.

19. The silicon-based mask according to claim 2, further comprising a first protection layer and a second protection layer, wherein the first protection layer is located on a side of the first silicon wafer away from the second silicon wafer, and the second protection layer is located on a side of the second silicon wafer away from the first silicon wafer.

20. The silicon-based mask according to claim 3, further comprising a first protection layer and a second protection layer, wherein the first protection layer is located on a side of the first silicon wafer away from the second silicon wafer, and the second protection layer is located on a side of the second silicon wafer away from the first silicon wafer.
